(19) United States
(12) Patent Application Publication
(10) Pub. No.: US 2026/0320268 A1
(43) Pub. Date: Oct. 15, 2026

(54) SIMULATED ANNEALING

(71) Applicant: GDM Holding LLC, Mountain View, CA (US)

(72) Inventors: Benoit Schillings, Los Altos Hills, CA (US); Xiaoqing Xu, Mountain View, CA (US); David Andre, San Francisco, CA (US); Jeffrey Bush, Los Altos, CA (US)

(21) Appl. No.: 19/174,055

(22) Filed: Apr. 9, 2025

(51) Int. Cl. G06F 30/32

(52) U.S. Cl. CPC G06F 30/32

(57) ABSTRACT

The technology involves determining physically compact, cost-efficient and/or computationally fast ICs that achieve a target functionality. According to one aspect, a method includes executing simulated annealing on a first circuit design to reduce a gate count or a depth of the first circuit design. The simulated annealing includes performing one or more first mutations to the first circuit design to yield a second circuit design, and stochastically evaluating the second circuit design based at least on a gate count or a depth of the second circuit design. Based at least on a result of stochastically evaluating the second circuit design, either the second circuit design is accepted or one or more second mutations to the second circuit design are performed.

### BACKGROUND

Integrated circuit (IC) development, involving design and fabrication, can be complicated and time consuming. The process can be particularly challenging with specialized integrated circuits, such as application-specific integrated circuits (ASICs) or system-on-chip (SoC) devices having many on-chip components such as transistors. There are a variety of approaches that have been employed to design such devices.

A concern in IC design is optimizing performance, power, and area (PPA). Optimization of PPA may include, for a given target functionality, reducing the total quantity of circuit components in an IC design, reducing the overall complexity of an IC design, and/or reducing the quantity of complex circuit components in an IC design. Each of these, individually and in concert, may improve performance, decrease power and resource consumption, and/or decrease the size or footprint of an IC design.

### SUMMARY

The disclosed technology relates to determining physically compact, cost-efficient and/or computationally fast ICs that achieve a target functionality. Aspects of the technology include searching a gate-network space for a smaller, if not minimal, gate network to achieve a target function (e.g., a k-bit multiplier) using simulated annealing. By exploiting vectorization, parallelism and low-level programming in a selected language, gate networks can be searched very quickly (e.g., millions of gate networks per second), which can enable very large quantities of gate networks (e.g., billions) to be explored in a relatively short amount of time (e.g., within a couple of hours). By way of example, the disclosed technology can determine gate networks that are smaller than the smallest gate networks determined by other approaches.

According to one aspect of the technology, a method includes executing, by one or more processors, simulated annealing on a first circuit design to reduce a gate count or a depth of the first circuit design, wherein the simulated annealing includes: performing one or more first mutations to the first circuit design to yield a second circuit design; stochastically evaluating the second circuit design based at least on a gate count or a depth of the second circuit design; and determining, based at least on a result of stochastically evaluating the second circuit design, either to a) accept the second circuit design or b) perform one or more second mutations to the second circuit design.

In an example, the one or more first mutations may include a migration.

Alternatively or additionally to the above, the one or more first mutations may include an ABC mutation.

Alternatively or additionally to the above, the one or more first mutations may include a proximity-based mutation.

Alternatively or additionally to the above, the one or more first mutations may include a genetic mutation.

Alternatively or additionally to the above, the one or more first mutations may include an automatically defined function (ADF).

Alternatively or additionally to the above, performing the one or more first mutations may include: performing the one or more first mutations includes: determining a channel of the first circuit design; performing the one or more first mutations to only the channel to yield a mutated channel; and inserting the mutated channel into the first circuit design to yield the second circuit design.

Alternatively or additionally to the above, stochastically evaluating the second circuit design may include determining a correctness of the second circuit design by comparing one or more entries of a first truth table for the second circuit design to one or more entries of a second truth table corresponding to a target logical function of the first and second circuit designs. Here, the one or more entries of the first truth table and the one or more entries of the second truth table may be randomly sampled from the first and second truth tables.

Alternatively or additionally to the above, the simulated annealing may further include, responsive to determining to perform the one or more second mutations to the second circuit design: performing one or more second mutations to the second circuit design to yield a third circuit design; stochastically evaluating the third circuit design based at least on a gate count or a depth of the third circuit design; and determining, based at least on a result of stochastically evaluating the third circuit design, either to a) accept the third circuit design or b) perform one or more third mutations to the third circuit design.

Alternatively or additionally to the above, the first circuit design may be represented by a directed acyclic graph (DAG) having a two-dimensional coordinate system corresponding to placement of the first circuit design. Here, the one or more first mutations may be based on a reward function based on a) parameters for synthesis and placement of the first circuit design and b) two-dimensional coordinate system.

According to another aspect of the technology, a system is provided that comprises memory configured to store a first circuit design. The one or more processors are configured to execute simulated annealing on a first circuit design to reduce a gate count or a depth of the first circuit design by being configured to perform one or more first mutations to the first circuit design to yield a second circuit design; stochastically evaluate the second circuit design based at least on a gate count or a depth of the second circuit design; and determine, based at least on a result of stochastically evaluating the second circuit design, either to a) accept the second circuit design or b) perform one or more second mutations to the second circuit design.

In an example, the one or more first mutations may include a migration.

Alternatively or additionally to the above, the one or more first mutations may include an ABC mutation.

Alternatively or additionally to the above, the one or more first mutations may include a proximity-based mutation.

Alternatively or additionally to the above, the one or more first mutations may include a genetic mutation.

Alternatively or additionally to the above, the one or more first mutations may include an automatically defined function (ADF).

Alternatively or additionally to the above, the one or more processors may be configured to perform the one or more first mutations by being further configured to: determine a channel of the first circuit design; perform the one or more first mutations to only the channel to yield a mutated channel; and insert the mutated channel into the first circuit design to yield the second circuit design.

Alternatively or additionally to the above, the one or more processors may be configured to stochastically evaluate the second circuit design by being further configured to determine a correctness of the second circuit design by comparing one or more entries of a first truth table for the second circuit design to one or more entries of a second truth table corresponding to a target logical function of the first and second circuit designs. Here, the one or more entries of the first truth table and the one or more entries of the second truth table may be randomly sampled from the first and second truth tables.

Alternatively or additionally to the above, the one or more processors may be further configured to responsive to a determination to perform the one or more second mutations to the second circuit design: perform one or more second mutations to the second circuit design to yield a third circuit design; stochastically evaluate the third circuit design based at least on a gate count or a depth of the third circuit design; and determine, based at least on a result of stochastically evaluating the third circuit design, either to a) accept the third circuit design or b) perform one or more third mutations to the third circuit design.

Alternatively or additionally to the above, the first circuit design may be represented by a directed acyclic graph (DAG) having a two-dimensional coordinate system corresponding to placement of the first circuit design. Here, the one or more first mutations may be based on a reward function based on a) parameters for synthesis and placement of the first circuit design and b) two-dimensional coordinate system.

### BRIEF DESCRIPTION OF THE DRAWINGS

FIG. 1 illustrates an integrated circuit design flow in accordance with aspects of the technology.

FIG. 2 illustrates an example system that may be employed with aspects of the technology.

FIG. 3 illustrates an example of a block diagram representing circuit design optimization in accordance with aspects of the technology.

FIG. 4 illustrates an example of a block diagram representing simulated annealing for correctness in accordance with aspects of the technology.

FIG. 5 illustrates an example of a block diagram representing simulated annealing for reduction of gate counts in accordance with aspects of the technology.

FIG. 6 illustrates an example of a channel in accordance with aspects of the technology.

FIG. 7 illustrates a graph of example average error for a 5-bit multiplier for iterations of simulated annealing according to other approaches and example average error for a 5-bit multiplier for iterations of simulated annealing in accordance with aspects of the technology.

FIG. 8 illustrates a graph of example minimum gate counts for a 5-bit multiplier for iterations of simulated annealing according to other approaches and example minimum gate counts for a 5-bit multiplier for iterations of simulated annealing in accordance with aspects of the technology.

FIG. 9 illustrates a graph of example average error for a 5-bit multiplier for iterations of simulated annealing including migration and example average error for a 5-bit multiplier for iterations of simulated annealing including migration and ABC mutations in accordance with aspects of the technology.

FIG. 10 illustrates a graph of example minimum gate counts for a 5-bit multiplier for iterations of simulated annealing including migration and example minimum gate counts for a 5-bit multiplier for iterations of simulated annealing including migration and ABC mutations in accordance with aspects of the technology.

FIG. 11 illustrates a graph of example average error for a 5-bit multiplier for iterations of simulated annealing including migration and example average error for a 5-bit multiplier for iterations of simulated annealing including migration and channels in accordance with aspects of the technology.

FIG. 12 illustrates a graph of example minimum gate counts for a 5-bit multiplier for iterations of simulated annealing including migration and example minimum gate counts for a 5-bit multiplier for iterations of simulated annealing including migration and channels in accordance with aspects of the technology.

FIG. 13 illustrates a graph of example average error for a 5-bit multiplier for iterations of simulated annealing including migration and example average error for a 5-bit multiplier for iterations of simulated annealing including migration and proximity-based mutations in accordance with aspects of the technology.

FIG. 14 illustrates a graph of example minimum gate counts for a 5-bit multiplier for iterations of simulated annealing including migration and example minimum gate counts for a 5-bit multiplier for iterations of simulated annealing including migration and proximity-based mutations in accordance with aspects of the technology.

FIG. 15 illustrates an example method in accordance with the above discussion.

### DETAILED DESCRIPTION

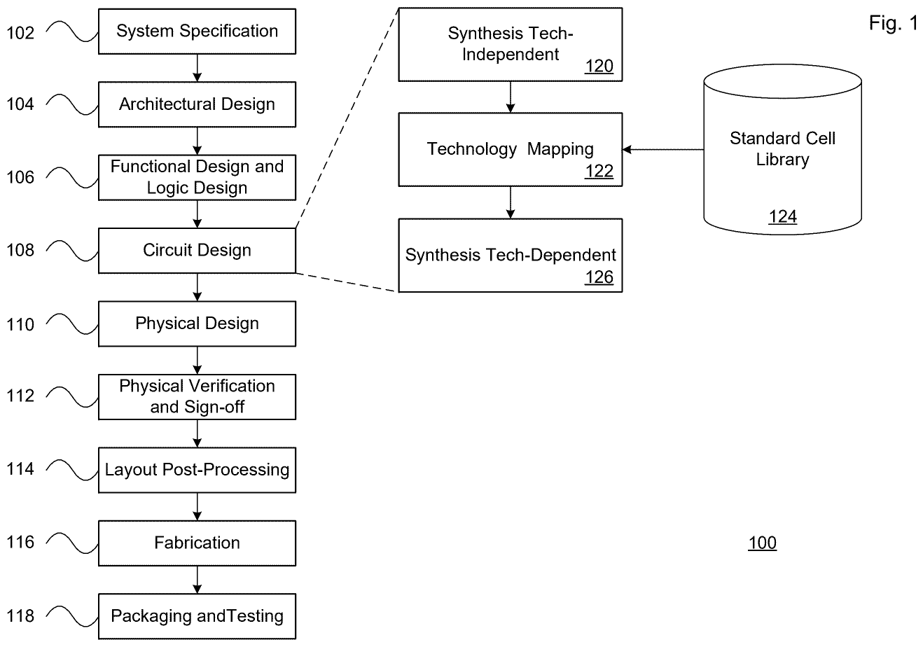

FIG. 1 illustrates an exemplary integrated circuit design flow 100 for use with aspects of the technology, including generating a circuit design and/or fabricating an integrated circuit that incorporates determining potential manufacturing defects in a mask pattern. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, according to aspects of the disclosed technology the system may perform partitioning, lower-layer routing, and upper-layer routing to generate a routing result, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves mapping the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### Example Integrated Circuit Development System

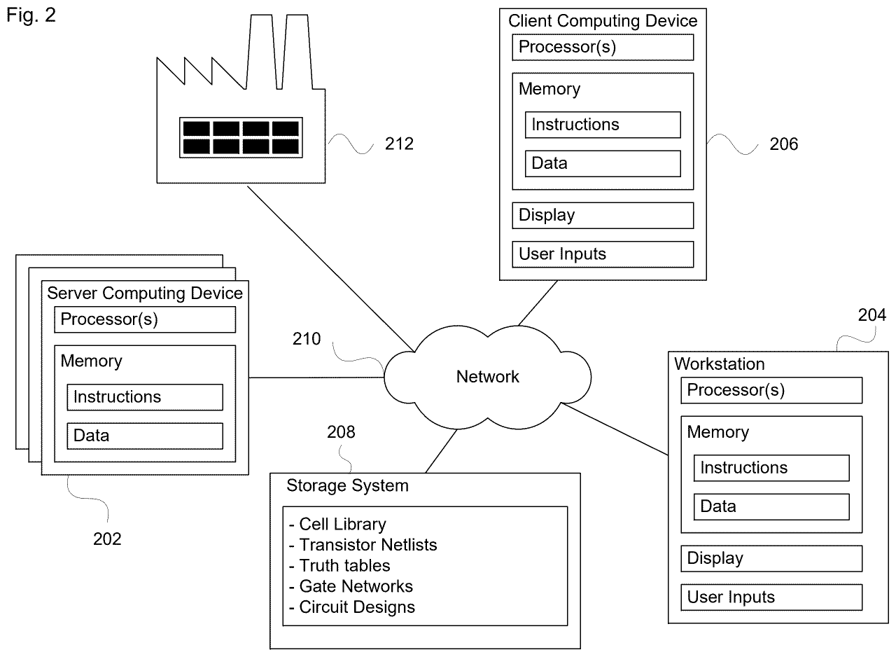

One example of a system for performing circuit design and fabrication is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing units (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance.

The data may be retrieved, stored or modified by the processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store, e.g., truth tables, circuit designs, gate networks, netlists and/or cell libraries, etc. It may also maintain functions for logic optimization, simulated annealing, mutations, and determining channels as well as for performing technology mapping and other processes described herein.

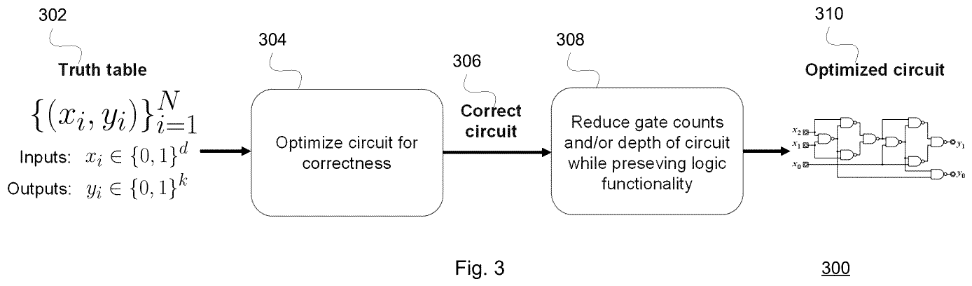

FIG. 3 illustrates an example of a block diagram 300 representing circuit design optimization in accordance with aspects of the technology. The disclosed circuit design optimization can include two phases of simulated annealing. An input to this circuit design optimization can be a target logical function, such as k-bit multiplication. By way of example, a target logical function can be represented by a truth table 302 including inputs and target outputs.

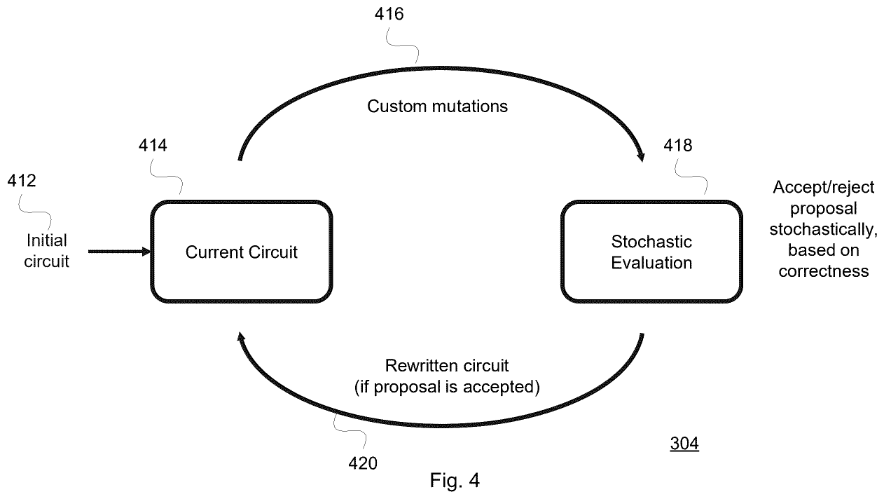

A first phase of simulated annealing 304 provides at least a threshold correctness for the target logical function. As used herein, “correctness” refers to a measure of whether a circuit design yields correct outputs for given inputs and a target logical function. This simulated annealing 304 is described further in association with FIG. 4.

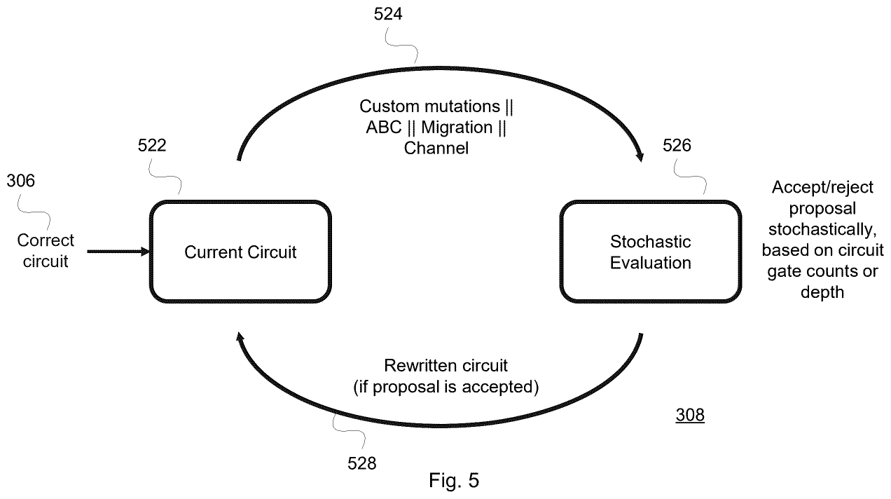

A second phase of simulated annealing 308 reduces gate counts and/or depth relative to a correct circuit design 306, which is an output of the simulated annealing 304. This simulated annealing 308 preserves the target logical function of the circuit design 306. This simulated annealing 308 is described further in association with FIG. 5. It is not required that the simulated annealing 308 for reduction of gate counts and/or depth be preceded by the simulated annealing 304 for correctness. Depth refers to the length of the longest path from primary inputs to primary outputs of the circuit design 306. Here, length is the quantity of nodes on the longest path.

The disclosed circuit design optimization can provide an optimized circuit design 310. The circuit diagram is a pictorial example of such an optimized circuit design, and is used for illustrative purposes only. The optimized circuit design provides the target logical function of the circuit design 306 but with fewer gates and/or reduced depth.

FIG. 4 illustrates an example of a block diagram representing simulated annealing 304 for correctness in accordance with aspects of the technology. This simulated annealing 304 includes performing mutations 416 to a current circuit design 414, beginning with an initial circuit design 412. The initial circuit design 412 may be selected at random, regardless of the target logical function. The simulated annealing 304, and the mutations 416 thereof, change the initial circuit design 412 to provide the target logical function with at least a certain level of correctness (e.g., a threshold correctness score). The correctness of the mutated circuit design may be quantified via a correctness score, which may be a percentage of entries of a truth table for the mutated circuit design that are correct. Correct entries of the truth table for the mutated circuit design may be determined by comparing entries of the truth table of the mutated circuit design to corresponding entries of the truth table 302 of the target logical function. If the size of the truth tables is such that computing the truth table for the mutated circuit design and/or comparing all the entries thereof would consume too many resources (e.g., time, memory), then entries of the truth tables may be sub-sampled (e.g., randomly) so as to consider a subset of entries of the truth table 306 of the target logical function.

These mutations 416 can include mutations that are picked stochastically. Multiple mutations can be made to the current circuit design 414. The mutations 416 can include multiple types of mutations. For instance, a mutation can include changing the type of logic operation of one or more gates of the current circuit design 414 (e.g., changing an AND gate to an OR gate). A mutation can include changing an input (e.g., a parent) of one or more gates of a circuits of the current circuit design 414. By way of example, a mutation may change a connection of a gate of the current circuit design 414 from receiving, as an input, the output from a first gate to receiving, as an input, the output from a second gate. As another example, a mutation may change a connection of a gate of the current circuit design 414 from receiving, as inputs, outputs from a first gate and a second gate to receiving, as inputs, outputs from that first gate, that second gate, and a third gate (e.g., increasing the quantity of inputs of a gate).

As indicated at 418, the mutated circuit design is evaluated stochastically based on correctness of the mutated circuit design. If the mutated circuit design has at least a threshold correctness score (e.g., at least 75-80% of entries of a truth table for the mutated circuit design are correct, or more or less), then the stochastic evaluation can accept the mutated circuit design as a correct circuit design (e.g., the correct circuit design 306 shown in FIG. 3). If the mutated circuit design does not have at least the threshold correctness score, then the stochastic evaluation can reject the mutated circuit design. In this case, another iteration of the simulated annealing 304 is performed and the mutated circuit design becomes the current circuit design 414. The mutations 416 are made to the current circuit design 414 as described above. One or more mutations of a current iteration can be in addition to and/or replace one or more of the mutations from a previous iteration. By way of example, each iteration of the simulated annealing 304 can include three to ten mutations.

FIG. 5 illustrates an example of a block diagram representing simulated annealing 308 for reduction of gate counts in accordance with aspects of the technology. This simulated annealing 308 includes performing mutations 524 to a current circuit design 522, beginning with the correct circuit design 306 from the simulated annealing 304. The simulated annealing 308 change the correct circuit design 306 to reduce gate count and/or depth relative to the correct circuit design 306.

These mutations 524 can be picked stochastically. Multiple mutations can be made to the current circuit design 522. The mutations 524 can include multiple types of mutations. For instance, a mutation can include changing the type of logic operation of one or more gates of the current circuit design 522 (e.g., changing an AND gate to an OR gate). A mutation can include changing an input (e.g., a parent) of one or more gates of a circuits of the current circuit design 522. By way of example, a mutation may change a connection of a gate of the current circuit design 522 from receiving, as an input, the output from a first gate to receiving, as an input, the output from a second gate. As another example, a mutation may change a connection of a gate of the current circuit design 522 from receiving, as inputs, outputs from a first gate and a second gate to receiving, as inputs, outputs from that first gate, that second gate, and a third gate (e.g., increasing the quantity of inputs of a gate).

Alternatively or in addition, the mutations 524 can include one or more ABC mutations to the current circuit design 522. As used herein, “ABC mutations” refer to mutations from the ABC open source library for logic-based circuit synthesis and verification that includes circuit manipulation commands. By way of example, these ABC mutations can include compression and expansion algorithms, modifications based on Boolean algebra, and/or operations including transforming a circuit from an and-inverter graph (AIG) to a majority inverter graph (MIG), and then back to an AIG.

Alternatively or in addition, the mutations 524 can include executing circuit subroutines that compute a consistent truth table for a given number of inputs to the current circuit design 522. Non-limiting examples of these circuit subroutines include automatically defined functions (ADFs). As used herein, “ADFs” refer to subroutines that are dynamically evolved during execution of genetic programming. By way of example, a specific area of the current circuit design 522 can be defined as a “subroutine” or ADF area. This ADF area can be used by a main execution branch (e.g., a main circuit), as long as arity of the ADF is preserved. An ADF can mimic human design and result in faster convergence times than other approaches.

Alternatively or in addition, the mutations 524 can include genetic mutations. For example, the mutations 524 can include cellular encoding methods that “grow” a circuit from a seed circuit.

Alternatively or in addition, the mutations 524 can include mutations of a “channels” of the current circuit design 522. As used herein, “channels” refer to sub-circuits of the current circuit design 522 that are completely dependent on one or more selected input gates (also referred herein as nodes) and include one or more output gates. Channels may or may not include one or more intermediate gates. However, if a channel includes intermediate gates, those intermediates gates are completely independent from the rest of the current circuit design 522. That is, any intermediate gates do not have an input or output outside the channel. A channel can be optimized to reduce the gate count and/or depth of the channel while maintaining the output of the channel. By inserting the optimized channel into the current circuit design 522 in place of the original channel, the overall gate count and/or depth of the current circuit design 522 is reduced.

The simulated annealing 308 can include determining a channel of the current circuit design 522. The current circuit design 522 can be represented as a directed acyclic graph (DAG). By way of example, whether a given set of input nodes and output nodes of a DAG define a channel can be determined. A KMN-channel includes no more than K output nodes and no more than M input nodes, where the values of the rest of the channel can be computed solely from the input nodes, and no other nodes of the current circuit design 522 are dependent on the nodes of the channel. The quantity of the intermediate nodes is at least N.

According to aspects of technology, a DAG may have a two-dimensional coordinate system (e.g., a grid having an x-axis and a y-axis) corresponding to placement of a physical circuit associated with the DAG. Each node (e.g., gate) of a DAG may have a set of coordinates associated therewith (e.g., x-y coordinates) corresponding to placement of a given gate. The simulated annealing 308 may be based on a reward function or metric. By way of example, the mutations 524 can be based on a reward function or metric. This reward function or metric may be based on parameters for synthesis and placement of a circuit design, such as half-parameter wirelength and/or gate density requirements. Parameters associated with synthesis and placement of a circuit design may be described in terms of the two-dimensional coordinate system of the DAG. Thus, the simulated annealing 308 may not only reduce gate counts, but also consider parameters for synthesis and placement of the circuit design.

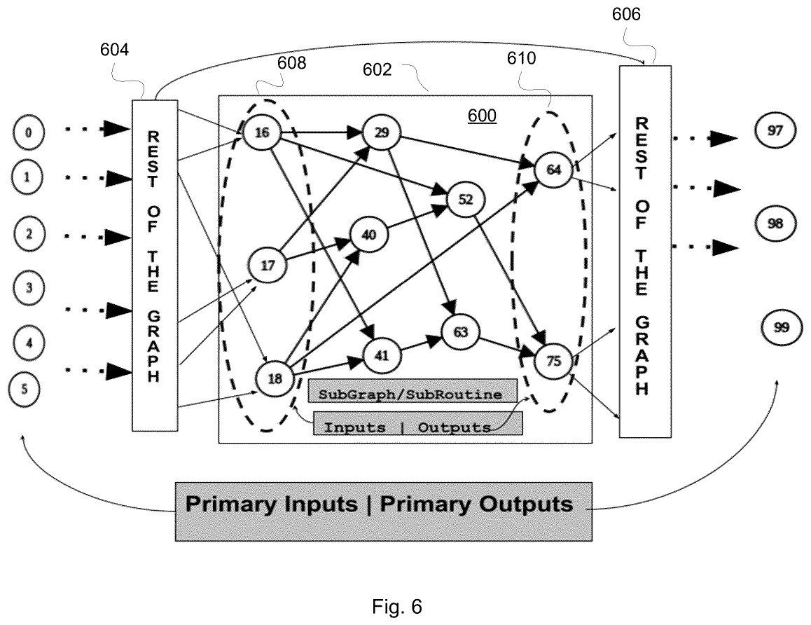

FIG. 6 illustrates an example of a channel 600 in accordance with aspects of the technology. The channel 600 is shown as a portion of a DAG for a larger circuit design. The channel 600 can also be referred to as a “SubRoutine” or a “SubGraph”. The box 602 represents the boundaries of the channel 600. The box 604 represents the portion of the DAG that precedes the channel 600 and the box 606 represents the portion of the DAG that succeeds the channel 600. Nodes 0, 1, 2, 3, 4 and 5 are primary inputs of the larger circuit design and nodes 97, 98 and 99 are primary outputs of the larger circuit design. Nodes 16, 17 and 18 (encircled by dashed oval 608) are inputs of the channel 600. Nodes 64 and 75 (encircled by dashed oval 610) are outputs of the channel 600.

Determining a channel can include looping over all nodes of a DAG of a circuit design (e.g., the current circuit design 522) one by one and using that node as a pivot element. That pivot element can be added to an output node list. The inputs to that pivot element can be added to an input node list. Elements of the input node list can be looped through one by one and a backward search can be performed in a depth-first search fashion. Subsequently, the input node list and the output node list can be cleared or emptied.

A backward search can be based at least on the input nodes (e.g., input node list), the intermediate nodes (e.g., intermediate node list), the output nodes (e.g., output nodes list), the current element of an input node being processed, and/or how far back from that current element to search (e.g., a quantity of “hops”). This backward search may include a forward search to increase the size of the channel 600. Parents of the current element can be designated as an input node (e.g., added to the input node list). The current element can be designed as an intermediate node or an output node (e.g., move the current element to the intermediate node list or the output node list). Elements can be looped over one by one in a depth first manner from the input node list and the output node list and a forward search can be performed. Parents of the current element can be looped over and a backward search can be performed.

A forward search can be based at least on the input nodes (e.g., input node list), the intermediate nodes (e.g., intermediate node list), the output nodes (e.g., output nodes list), the current element of an input node being processed, and/or how far back from that current element to search (e.g., a quantity of “hops”). This backward search can include adding required nodes in the sub-circuit. If the current element is in the input node list, then the children of the current element can be looped over one by one and can be performed after adding the current element to the output node list. If the current element is not designated as an input node (e.g., not in the input node list), then the current element is not designated as an output node (e.g., removed from the output node list) and designated as an intermediate node (e.g., added to the intermediate node list). Children of the current element can be designated as output nodes (e.g., added to the output node list). Children of the current element can be looped over and a forward search can be performed on the children.

Designating nodes as input, intermediate or output nodes (e.g., adding or removing nodes from the input node list, the intermediate node list or the output node list) can include designating the children of elements designated as intermediate nodes can be designated as intermediate or output nodes (e.g., adding the children of all the elements of the intermediate node list to the intermediate node list or the output node list). Designating nodes as input, intermediate or output nodes can include designating the parents of elements designated as output nodes can be designated as intermediate or input nodes (e.g., adding the children of all the elements of the output node list to the intermediate node list or the input node list). All elements designated as input nodes can be looped over and whether there is a direct in-ward edge to that element from any element designated as an input, intermediate or output node. If there is a direct in-ward edge, then that element can be designated as an intermediate or output node (e.g., move the current element to the output node list or the intermediate node list), and the parents of that element can be designated as input nodes (e.g., added to the input node list).

By way of example, with reference to FIG. 6, determining the channel 600 can begin with nodes 52 and 63 being designated as input nodes and node 75 being designated as an output node. A backward search from the node 52 results in nodes 16 and 40 being designated as input nodes and node 52 changing designation from input node to intermediate node. According to aspects of the technology, determining the channel 600 ensures that, for a path from a primary input to a primary output, all nodes on that path are included within the channel 600.

Referring back to FIG. 5, as indicated at 524 the mutated circuit design is evaluated stochastically based on the gate count and/or depth of the mutated circuit design. If the mutated circuit design has at most a threshold gate count and/or a threshold depth, then the stochastic evaluation can accept the mutated circuit design. If the mutated circuit design has more than a threshold gate count and/or a threshold depth, then the stochastic evaluation can reject the mutated circuit design. In this case, another iteration of the optimization 308 is performed and the mutated circuit design becomes the current circuit design 522. The mutations 526 are made to the current circuit design 522 (the previous mutated circuit design) as described above. One or more mutations of a current iteration can be in addition to and/or replace one or more of the mutations from a previous iteration. By way of example, each iteration of the optimization 308 can include three to ten mutations.

The simulated annealing 308 can include analyzing results from each simulated annealing thread using a “suggester”. This suggester can make suggestions for mutations to include a subsequent (next) iteration. This can enable simulated annealing threads to continue at high speeds while obtaining benefits of intense computation about what mutations to try.

The simulated annealing 308 can include a temperature management scheme such that different nodes of the current circuit design 522 have different annealing schedules. This can improve variety and provide a portfolio approach that includes some simulated annealing threads being focused on exploitation and other simulated annealing threads being focused on exploration. Exploitation refers to accepting a change only if there is an improvement in a reward function or metric. Exploration refers accepting a change even if there is a degradation in a reward function or metric, which may assist in jumping out of (exiting) a local minima.

The simulated annealing 308 can include permitting additional nodes (e.g., extra space) to be introduced into the current circuit design 522, even if most of the additional nodes are not connected to the outputs. Although multiple iterations may change non-essential nodes, later iterations and mutations thereof may use these non-essential nodes to result in larger scale changes to the current circuit design 522.

The simulated annealing 308 can include evolutionary synthesis on transistor circuits where the connectivity does not need to be as simple as in Boolean circuits, rather than operating directly on gates. Instead of a gate list where each gate has one or more inputs and one output, evolutionary synthesis can include more general circuits where each component has one or more ports. Each port can be connected arbitrarily to one or more other ports in the circuit. Although may be a more complicated problem, it can still be solved using one or more approaches disclosed herein. By way of example, pull up and pull down parts of a circuit may be constructed in synchrony.

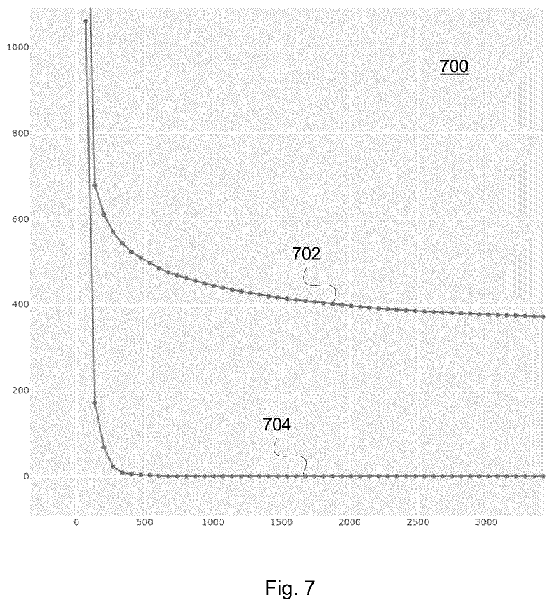

FIG. 7 illustrates a graph 700 of example average error for a 5-bit multiplier for iterations of simulated annealing according to other approaches and example average error for a 5-bit multiplier for iterations of simulated annealing in accordance with aspects of the technology. The graph 700 shows average error on the vertical axis and iterations in millions on the horizontal axis. The curve 702 represents average error for other simulated annealing approaches. The curve 704 represents average error for the disclosed simulated annealing approaches. One or more of the disclosed simulated annealing approaches can provide an average error of near zero or zero after approximately 400-450 million iterations. In contrast, other simulated annealing approaches have an average error of approximately 500 after approximately 400-450 million iterations. Moreover, the other simulated annealing approaches do not achieve a near-zero average error and, at best, achieves an average error of approximately 380 after approximately 3.5 billion iterations.

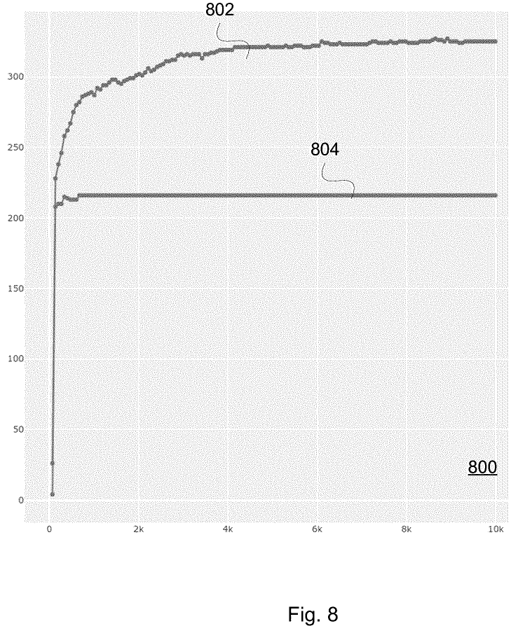

FIG. 8 illustrates a graph 800 of example minimum gate counts for a 5-bit multiplier for iterations of simulated annealing according to other approaches and example minimum gate counts for a 5-bit multiplier for iterations of simulated annealing in accordance with aspects of the technology. The graph 800 shows minimum gate count on the vertical axis and iterations in millions on the horizontal axis. The curve 802 represents average error for other simulated annealing approaches. The curve 804 represents average error for the disclosed simulated annealing approaches. One or more of the disclosed simulated annealing approaches can converge to a minimum gate count of approximately 220 after approximately 300-400 million iterations. In contrast, other simulated annealing approaches do not converge to a minimum gate count until after at least 4 billion iterations. Moreover, the other simulated annealing approaches converge to a minimum gate count of approximately 325.

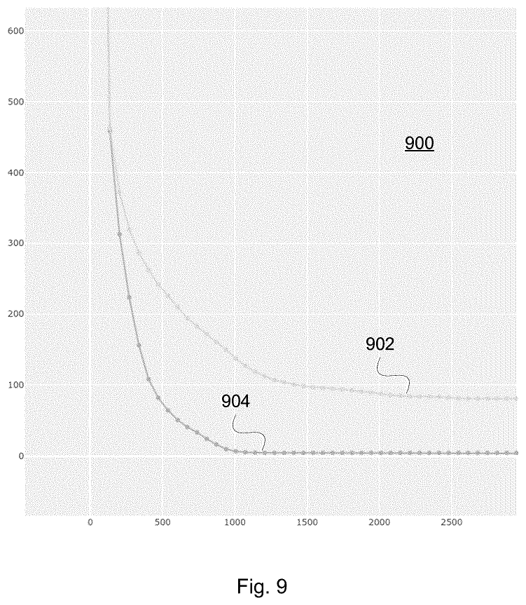

FIG. 9 illustrates a graph 900 of example average error for a 5-bit multiplier for iterations of simulated annealing including migration and example average error for a 5-bit multiplier for iterations of simulated annealing including migration and ABC mutations in accordance with aspects of the technology. The graph 900 shows average error on the vertical axis and iterations in millions on the horizontal axis. The curve 902 represents average error for simulated annealing including migration whereas the curve 904 represents average error for simulated annealing including migration and ABC mutations. Migration and ABC mutations can provide an average error of near zero or zero after approximately 1 billion iterations. In contrast, migration without ABC mutations can provide an average error of approximately 240 after approximately one billion iterations. Moreover, migration without ABC mutations does not achieve a near-zero average error and, at best, achieves an average error of approximately 90 after approximately 2 billion iterations.

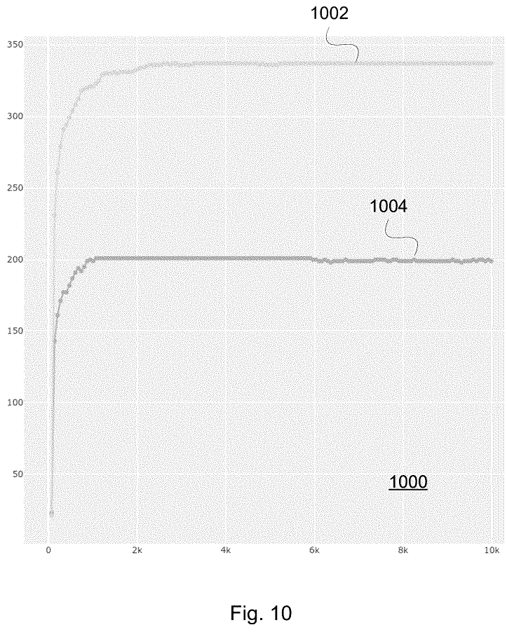

FIG. 10 illustrates a graph 1000 of example minimum gate counts for a 5-bit multiplier for iterations of simulated annealing including migration and example minimum gate counts for a 5-bit multiplier for iterations of simulated annealing including migration and ABC mutations in accordance with aspects of the technology. The graph 1000 shows minimum gate count on the vertical axis and iterations in millions on the horizontal axis. The curve 1002 represents minimum gate count for simulated annealing including migration whereas the curve 1004 represents minimum gate count for simulated annealing including migration and ABC mutations. Migration and ABC mutations can converge to a minimum gate count of approximately 200 after approximately 1 billion iterations. In contrast, migration without ABC mutations does not converge to a minimum gate count until after at least 2 billion iterations. Moreover, the other simulated annealing approaches converge to a minimum gate count of approximately 330.

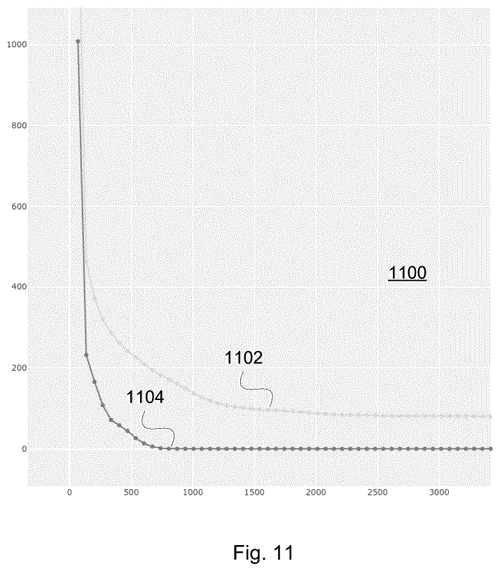

FIG. 11 illustrates a graph 1100 of example average error for a 5-bit multiplier for iterations of simulated annealing including migration and example average error for a 5-bit multiplier for iterations of simulated annealing including migration and channels in accordance with aspects of the technology. The graph 1100 shows average error on the vertical axis and iterations in millions on the horizontal axis. The curve 1102 represents average error for simulated annealing including migration whereas the curve 1104 represents average error for simulated annealing including migration and channels. Migration and channels can provide an average error of near zero or zero after approximately 750 million iterations. In contrast, migration without channels can provide an average error of approximately 190 after approximately one billion iterations. Moreover, migration without channels does not achieve a near-zero average error and, at best, achieves an average error of approximately 100 after approximately 1.5 billion iterations.

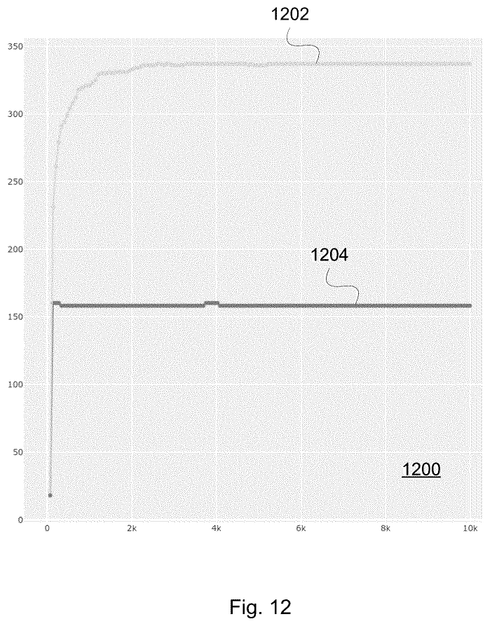

FIG. 12 illustrates a graph 1200 of example minimum gate counts for a 5-bit multiplier for iterations of simulated annealing including migration and example minimum gate counts for a 5-bit multiplier for iterations of simulated annealing including migration and channels in accordance with aspects of the technology. The graph 1200 shows minimum gate count on the vertical axis and iterations in millions on the horizontal axis. The curve 1202 represents minimum gate count for simulated annealing including migration whereas the curve 1204 represents minimum gate count for simulated annealing including migration and channels. Migration and channels can converge to a minimum gate count of approximately 160 after approximately 400 million iterations. In contrast, migration without channels does not converge to a minimum gate count until after at least 2 billion iterations. Moreover, the other simulated annealing approaches converge to a minimum gate count of approximately 330.

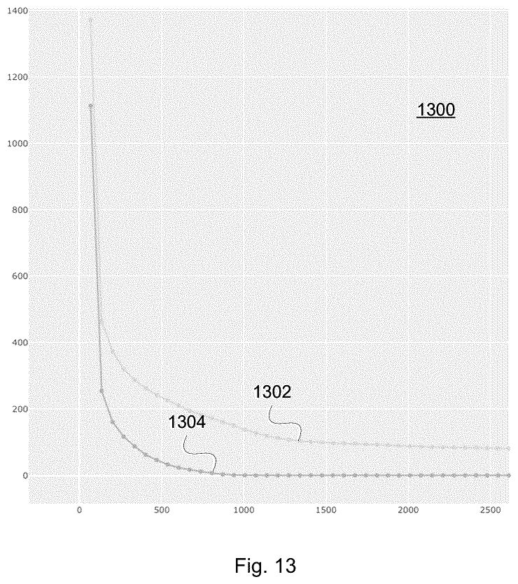

FIG. 13 illustrates a graph 1300 of example average error for a 5-bit multiplier for iterations of simulated annealing including migration and example average error for a 5-bit multiplier for iterations of simulated annealing including migration and proximity-based mutations in accordance with aspects of the technology. The graph 1300 shows average error on the vertical axis and iterations in millions on the horizontal axis. The curve 1302 represents average error for simulated annealing including migration whereas the curve 1304 represents average error for simulated annealing including migration and proximity-based mutations. Migration and proximity-based mutations can provide an average error of near zero or zero after approximately 750 million iterations. In contrast, migration without channels can provide an average error of approximately 190 after approximately one billion iterations. Moreover, migration without proximity-based mutations does not achieve a near-zero average error and, at best, achieves an average error of approximately 100 after approximately 1.5 billion iterations.

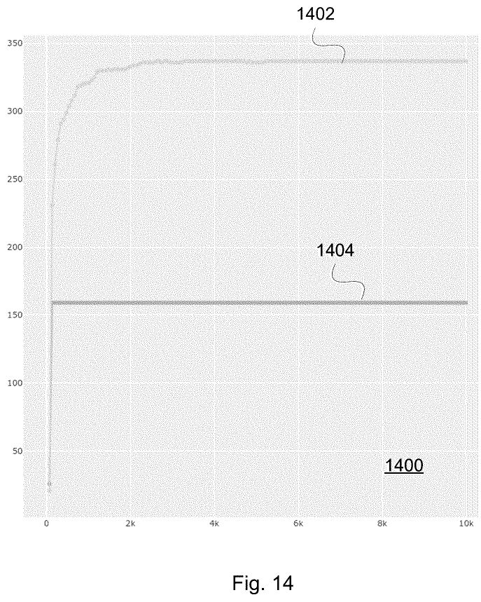

FIG. 14 illustrates a graph 1400 of example minimum gate counts for a 5-bit multiplier for iterations of simulated annealing including migration and example minimum gate counts for a 5-bit multiplier for iterations of simulated annealing including migration and proximity-based mutations in accordance with aspects of the technology. The graph 1400 shows minimum gate count on the vertical axis and iterations in millions on the horizontal axis. The curve 1402 represents minimum gate count for simulated annealing including migration whereas the curve 1404 represents minimum gate count for simulated annealing including migration and proximity-based mutations. Migration and proximity-based mutations can converge to a minimum gate count of approximately 160 after approximately 400 million iterations. In contrast, migration without proximity-based mutations does not converge to a minimum gate count until after at least 2 billion iterations. Moreover, the other simulated annealing approaches converge to a minimum gate count of approximately 330.

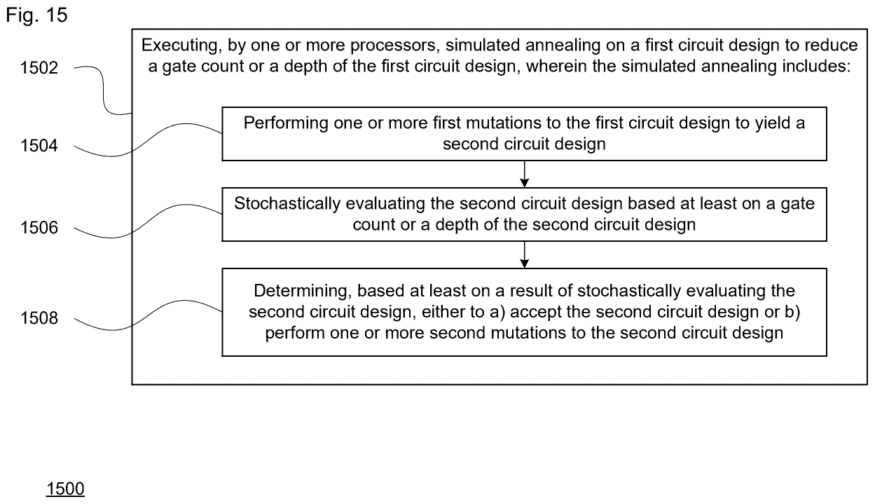

FIG. 15 illustrates an example method 1500 in accordance with the above discussion. The method 1500 includes, at block 1502, executing, by one or more processors, simulated annealing on a first circuit design to reduce a gate count or a depth of the first circuit design. The simulated annealing includes, at block 1504, performing one or more first mutations to the first circuit design to yield a second circuit design. The simulated annealing includes, at block 1506, stochastically evaluating the second circuit design based at least on a gate count or a depth of the second circuit design. The simulated annealing includes, at block 1508, determining, based at least on a result of stochastically evaluating the second circuit design, either to a) accept the second circuit design or b) perform one or more second mutations to the second circuit design.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method, comprising:
executing, by one or more processors, simulated annealing on a first circuit design to reduce a gate count or a depth of the first circuit design, wherein the simulated annealing includes:
performing one or more first mutations to the first circuit design to yield a second circuit design;
stochastically evaluating the second circuit design based at least on a gate count or a depth of the second circuit design; and
determining, based at least on a result of stochastically evaluating the second circuit design, either to a) accept the second circuit design or b) perform one or more second mutations to the second circuit design.

2. The method of claim 1, wherein the one or more first mutations include a migration.

3. The method of claim 1, wherein the one or more first mutations include an ABC mutation.

4. The method of claim 1, wherein the one or more first mutations include a proximity-based mutation.

5. The method of claim 1, wherein the one or more first mutations include a genetic mutation.

6. The method of claim 1, wherein the one or more first mutations include an automatically defined function (ADF).

7. The method of claim 1, wherein performing the one or more first mutations includes:
determining a channel of the first circuit design;
performing the one or more first mutations to only the channel to yield a mutated channel; and
inserting the mutated channel into the first circuit design to yield the second circuit design.

8. The method of claim 1, wherein stochastically evaluating the second circuit design includes determining a correctness of the second circuit design by comparing one or more entries of a first truth table for the second circuit design to one or more entries of a second truth table corresponding to a target logical function of the first and second circuit designs.

9. The method of claim 8, wherein the one or more entries of the first truth table and the one or more entries of the second truth table are randomly sampled from the first and second truth tables.

10. The method of claim 1, wherein the simulated annealing further includes, responsive to determining to perform the one or more second mutations to the second circuit design:
performing one or more second mutations to the second circuit design to yield a third circuit design;
stochastically evaluating the third circuit design based at least on a gate count or a depth of the third circuit design; and
determining, based at least on a result of stochastically evaluating the third circuit design, either to a) accept the third circuit design or b) perform one or more third mutations to the third circuit design.

11. The method of claim 1, wherein:
the first circuit design is represented by a directed acyclic graph (DAG) having a two-dimensional coordinate system corresponding to placement of the first circuit design; and
the one or more first mutations are based on a reward function or metric based on a) parameters for synthesis and placement of the first circuit design and b) two-dimensional coordinate system.

12. A system, comprising:
memory configured to store a first circuit design; and
one or more processors operatively coupled to the memory, the one or more processors being configured to execute simulated annealing on a first circuit design to reduce a gate count or a depth of the first circuit design by being configured to:
perform one or more first mutations to the first circuit design to yield a second circuit design;
stochastically evaluate the second circuit design based at least on a gate count or a depth of the second circuit design; and
determine, based at least on a result of stochastically evaluating the second circuit design, either to a) accept the second circuit design or b) perform one or more second mutations to the second circuit design.

13. The system of claim 12, wherein the one or more first mutations include a migration.

14. The system of claim 12, wherein the one or more first mutations include an ABC mutation.

15. The system of claim 12, wherein the one or more first mutations include a proximity-based mutation.

16. The system of claim 12, wherein the one or more first mutations include a genetic mutation.

17. The system of claim 12, wherein the one or more first mutations include an automatically defined function (ADF).

18. The system of claim 12, wherein the one or more processors are configured to perform the one or more first mutations by being further configured to:
determine a channel of the first circuit design;
perform the one or more first mutations to only the channel to yield a mutated channel; and
insert the mutated channel into the first circuit design to yield the second circuit design.

19. The system of claim 12, wherein the one or more processors are configured to stochastically evaluate the second circuit design by being further configured to determine a correctness of the second circuit design by a comparison of one or more entries of a first truth table for the second circuit design to one or more entries of a second truth table corresponding to a target logical function of the first and second circuit designs.

20. The system of claim 19, wherein the one or more entries of the first truth table and the one or more entries of the second truth table are randomly sampled from the first and second truth tables.

21. The system of claim 12, wherein the one or more processors are further configured to, responsive to a determination to perform the one or more second mutations to the second circuit design:
perform one or more second mutations to the second circuit design to yield a third circuit design;
stochastically evaluate the third circuit design based at least on a gate count or a depth of the third circuit design; and
determine, based at least on a result of stochastically evaluating the third circuit design, either to a) accept the third circuit design or b) perform one or more third mutations to the third circuit design.

22. The system of claim 12, wherein:
the first circuit design is represented by a directed acyclic graph (DAG) having a two-dimensional coordinate system corresponding to placement of the first circuit design; and
the one or more first mutations are based on a reward function or metric based on a) parameters for synthesis and placement of the first circuit design and b) two-dimensional coordinate system.
